(19) United States
(12) Patent Application Publication
(10) Pub. No.: US 2025/0308123 A1
(43) Pub. Date: Oct. 2, 2025

(54) ANIMATING WATER USING PROFILE BUFFER

(71) Applicant: Tencent America LLC, Palo Alto, CA (US)

(72) Inventors: Kui WU, Los Angeles, CA (US); Haozhe SU, Palo Alto, CA (US); Zhenyu MAO, Palo Alto, CA (US)

(73) Assignee: Tencent America LLC, Palo Alto, CA (US)

(21) Appl. No.: 19/093,064

(22) Filed: Mar. 27, 2025

Related U.S. Application Data
(60) Provisional application No. 63/573,435, filed on Apr. 2, 2024.

(51) Int. Cl. G06T 13/60; G06F 30/28; G06T 13/80

(52) U.S. Cl. CPC G06T 13/60; G06F 30/28; G06T 13/80; G06T 2210/24

(57) ABSTRACT

A plurality of initial values of a water wave function is defined. The water wave function is configured to simulate the water flow in a domain. A plurality of profile buffer values associated with the plurality of water waves of the water wave function is calculated. A plurality of water height values of the plurality of water waves of the water flow is determined. Each of the plurality of water height values is associated with a product of a direction weight value and an in-situ profile buffer value of a respective one of the plurality of water waves. A plurality of surface normal vectors of the plurality of water waves of the water flow is determined based on gradient vectors associated with the plurality of water height values. The water flow is rendered based on the plurality of water height values and the plurality of surface normal vectors.

### INCORPORATION BY REFERENCE

The present application claims the benefit of priority to U.S. Provisional Application No. 63/573,435, “ANIMATING WATER USING PROFILE BUFFER” filed on Apr. 2, 2024, which is incorporated by reference herein in its entirety.

### TECHNICAL FIELD

The present disclosure describes aspects generally related to the animation of water.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Water can play an important role in applications such as video games, contributing to both visual and interactive aspects of the user experience. One technique to create a realistic water surface animation is via a flowmap, such as a 2D velocity field texture, to advect the water displacement and normal textures at a runtime. While the flowmap technique stands out for its computational efficiency in animating water within video games, the flowmap may have limitations. One notable drawback is the potential for large distortion and stretching artifacts, such as in regions where the velocity magnitude is substantial. In the disclosure, an approach to real-time water animation is provided by leveraging a wavelet-based methodology enhanced by a pre-computed profile buffer technique to improve performance. The proposed technique aims to create water waves dynamically based on factors such as world position, time, and velocity present in the flowmap.

### SUMMARY

Aspects of the disclosure include methods and apparatuses for simulating water flow with a plurality of water waves. In some examples, an apparatus for water flow simulation includes processing circuitry.

According to an aspect of the disclosure, a method of simulating water flow with a plurality of water waves is provided. In the method, a plurality of initial values of a water wave function is defined. The water wave function is configured to simulate the water flow in a domain that includes a plurality of subregions. A plurality of profile buffer values associated with the plurality of water waves of the water wave function is calculated. Each of the plurality of profile buffer values is associated with a product of a wavelength, a wave basis value, and a channel value of a respective one of the plurality of water waves. A plurality of water height values of the plurality of water waves of the water flow is determined. Each of the plurality of water height values is associated with a product of a direction weight value and an in-situ profile buffer value of a respective one of the plurality of water waves. A plurality of surface normal vectors of the plurality of water waves of the water flow is determined based on gradient vectors associated with the plurality of water height values. The water flow is rendered based on the plurality of water height values and the plurality of surface normal vectors.

According to another aspect of the disclosure, an information processing apparatus is provided. The apparatus includes processing circuitry. The processing circuitry is configured to define a plurality of initial values of a water wave function. The water wave function is configured to simulate a plurality of water waves of water flow in a domain that includes a plurality of subregions. The processing circuitry is configured to calculate a plurality of profile buffer values associated with the plurality of water waves of the water wave function. Each of the plurality of profile buffer values is associated with a product of a wavelength, a wave basis value, and a channel value of a respective one of the plurality of water waves. The processing circuitry is configured to determine a plurality of water height values of the plurality of water waves of the water flow. Each of the plurality of water height values is associated with a product of a direction weight value and an in-situ profile buffer value of a respective one of the plurality of water waves. The processing circuitry is configured to determine a plurality of surface normal vectors of the plurality of water waves of the water flow based on gradient vectors associated with the plurality of water height values. The processing circuitry is configured to render the water flow based on the plurality of water height values and the plurality of surface normal vectors.

Aspects of the disclosure also provide a non-transitory computer-readable medium storing instructions which, when executed by a computer, cause the computer to perform any of the described methods for simulating water flow with a plurality of water waves.

### BRIEF DESCRIPTION OF THE DRAWINGS

Further features, the nature, and various advantages of the disclosed subject matter will be more apparent from the following detailed description and the accompanying drawings in which:

FIG. 1 is a schematic illustration of examples of simulated uniform water flow and circular water flow.

FIG. 2A is an example of a diagram of a simplified wave without interpolation.

FIG. 2B is an example of a diagram of a simplified wave with interpolation.

FIG. 3 is a schematic illustration of examples of simulated water flow based on adaptive limits of integration.

FIG. 4 is a schematic illustration of an example of a custom-designed map featuring a river scene.

FIG. 5 is a schematic illustration of comparisons between Riemann sum and Gaussian quadrature in water flow simulations.

FIG. 6 is a schematic illustration of an example of simulated water flow based on adaptive integration limits.

FIG. 7 is a schematic illustration of comparisons of various profile buffers in water flow simulation.

FIG. 8 shows a flow chart outlining a water flow simulation process according to some aspects of the disclosure.

FIG. 9 is a schematic illustration of a computer system in accordance with an aspect.

### DETAILED DESCRIPTION

Aspects of the disclosure includes methods and systems directed to water flow simulations.

Various methods have been provided for water flow simulation. For example, a partial differential equation (PDE)-based method may be used to simulate water flow based on precise spatial discretization. Linear wave theory was proposed to describe wave height dynamics η(x, t) at a position x (e.g., x =(z, x)) in a 2D simulation domain at time t. According to the linear wave theory, the wave height dynamics η(x, t) of a wave (or water wave) may be articulated in terms of frequencies as follows in equation (1):

$$η ( x , t ) = {\int }_{{R}^{2}} 𝒜 ( x , k , t ) cos ( k \cdot x - ω ( k ) t ) dk , \qquad Eq . ( 1 )$$

where the first term [symbol] (x, k, t) is an amplitude function (or amplitude field) that depends on k, x, and t. The second term cos (k·x−ω(k)t) represents a traveling wave. The wave vector k may be a two-dimensional frequency function such that k=|k| is a wave number of the wave and \hat{k}=k/k is a wave direction. The angular frequency ω(k)=\sqrt{gk} may represent a dispersion relation for deep water waves by encoding a speed of each wave based on its wavenumber k and a gravity g. To further elaborate on the equation (1) by employing a polar representation of the wave vector k, equation (1) may be revised into equation (2) as follows:

$$η ( x , t ) = {\int }_{0}^{2 π} {\int }_{0}^{∞} 𝒜 ( x , k , t ) cos ( k \cdot x - ω ( k ) t ) kdkd θ , \qquad Eq . ( 2 )$$

However, simulating the water flow based on the equation (2) may be time-consuming and processor intensive. Aspects of the present disclosure include decomposition of the amplitude field [symbol] and discretization of each decomposed component to expedite calculation of equation (2) in water flow simulation.

To decompose the amplitude field, the amplitude field [symbol] (x, k, t) in each time step may be evolved to more accurately depict wave movements. However, such an approach may require extensive computations. To simplify the amplitude field decomposition, input water flow may remain static. For example, the input water flow is considered as static and specified by a pre-computed flowmap. Thus, the amplitude field [symbol] may only be affected by positions and wave vectors. An example of the amplitude field decomposition is provided as follows in equation (3):

$$𝒜 ( x , k ) = A W ( x , θ ) ψ ( k ) , \qquad Eq . ( 3 )$$

where A serves as a constant factor for adjusting the wave strength (or wave amplitude) of a wave (or water wave), W(x, θ) indicates a direction weight and represents a weight associated with a wave direction θ of the wave at a spatial position x, and ψ(k) denotes a basis function of the wave.

To define the direction weight W(x, θ), a time-independent direction at the location x from the flowmap (or water flow) may be defined. The time-independent direction may be defined as a primary wave direction θₚ as follows in equation (4):

$${θ}_{p} ( x ) = arctan ( {υ}_{x} / {υ}_{z} ) , \qquad Eq . ( 4 )$$

where υₓ and υ_{z} are velocity components of the flowmap along the x-axis and z-axis, respectively. By assuming that a wave direction of a wave is in a vicinity of the primary wave direction, the corresponding weight W (x, θ) may be computed as follows in equation (5):

$$W ( x , θ ) = \{ \begin{matrix}1 - \vert θ - {θ}_{p} ( x ) \vert / C , & if 1 - \vert θ - {θ}_{p} ( x ) \vert \leq C \\ 0 , & otherwise\end{matrix} \qquad Eq . ( 5 )$$

where C is a half-width of an angle range with a non-zero weight, which may be defined in table 11. As shown in equation (5), the farther the angle θ deviates from the primary angle θₚ(x), the smaller the weight W (x, θ) becomes.

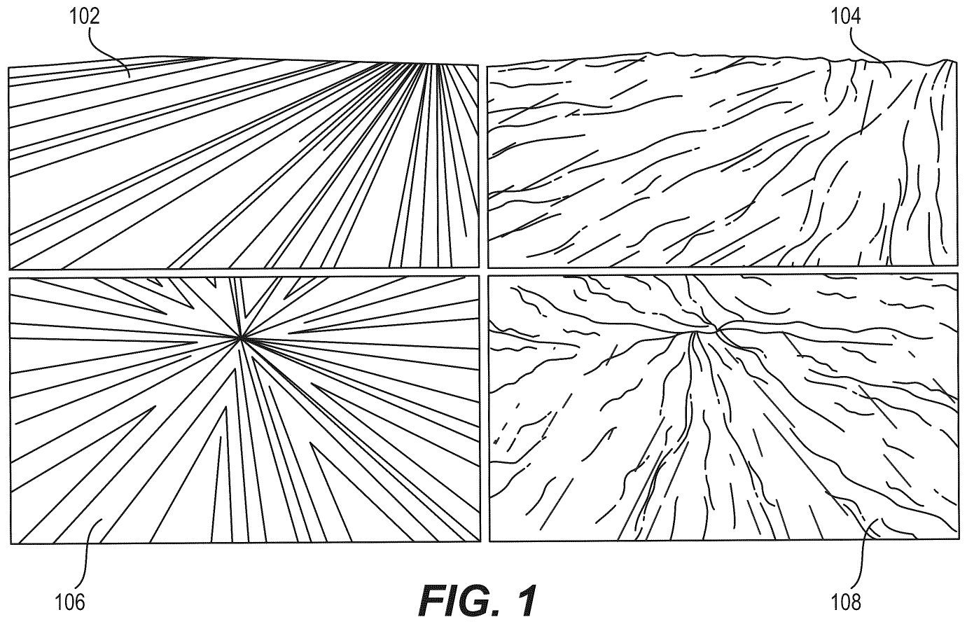

FIG. 1 shows comparisons between water flow simulation utilizing smaller and larger angle ranges with non-zero weights. As shown in FIG. 1, images (102) and (104) illustrate simulations of uniform water flow based on a consistent strength. Image (106) shows simulation of circular water flow based a small relative angle range, such as an angle range

$$[ - \frac{π}{8} , \frac{π}{8} ] ,$$

and image (108) shows simulation of circular water flow based on a large relative angle range, such as an angle range

$$[ - \frac{π}{2} , \frac{π}{2} ] .$$

The wave basis ψ(k) in equation (3) symbolizes a wave shape of a water wave with a representative wave number k in a frequency space. Various wave spectrums may be used as the wave basis. An example of the wave basis ψ(k) is Phillips spectrum. The Phillips spectrum may be provided as follows in Table 1.

TABLE 1
An example of the Phillips spectrum.

```
// wave basis
float phillips_spectrum (float waveNumber)
{
  float windSpeed=10.f;
  float A=2.f*PI/waveNumber;
  float B-expf (−1.8038 f * A * A/powf(windspeed, 4));
  return 0.1391 f * sqrtf (A * B) ;
}
```

As shown in Table 1, for a given wave number k of a water wave in the water flow, the wave shape may be defined as expf(−1.8038*A*A/powf(windspeed, 4)). A may be defined as 2π/k, and windspeed may be a preset value, such as 10.

By substituting equation (3) into equation (2), the wave height dynamics η(x, t) may further be defined as follows in equations (6) and (7):

$$η ( x , t ) = {\int }_{0}^{2 π} {\int }_{0}^{∞} A W ( x , θ ) ψ ( k ) cos ( k \cdot x - ω ( k ) t ) k d k d θ \qquad Eq . ( 6 )$$

$$= {\int }_{0}^{2 π} A W ( x , θ ) ( {\int }_{0}^{∞} ψ ( k ) cos ( k \cdot x - ω ( k ) t ) kdk ) d θ . \qquad Eq . ( 7 )$$

Performing a double integral to calculate η(x, t) via equation (7) for each pixel in a domain may be time-consuming, especially for high-resolution animations. Thus, a profile buffer Ψ̅(p, t) may be defined as follows in equation (8):

$$\overline{Ψ} ( p , t ) = {\int }_{0}^{∞} ψ ( k ) cos ( kp - ω ( k ) t ) kdk , \qquad Eq . ( 8 )$$

where p=\hat{k}·x is a projected position of a water wave at the position x. For example, p can be a projected position in a z-x space. By pre-computing the integral of Ψ̅(p, t), the original double integral in equation (7) may be converted into a single integral as follows in equation (9):

$$η ( x , t ) = {\int }_{0}^{2 π} A W ( x , θ ) \overline{Ψ} ( p , t ) d θ . \qquad Eq . ( 9 )$$

It is noted that the profile buffer Ψ̅(p, t) is a function of both p and t, requiring updates in every time step.

Calculating the integral of equation (9) can be a time-consuming process. To more efficiently solve the equation (9), discretization may be applied. For example, the integral of the profile buffer Ψ̅(p, t) in equation (8) may be solved based on a discretization approach. However, the integral of the profile buffer Ψ̅(p, t) may involve an infinite number of calculations when converted to a summation form. Thus, equation (8) may be approximated with a finite number of summations as follows in equation (10):

$$\overline{Ψ} ( p , t ) = {\sum }_{i = 0}^{{N}_{k} - 1} ψ ( {k}_{i} ) cos ( {k}_{i} p - ω ( {k}_{i} ) t ) {k}_{i} Δ k , \qquad Eq . ( 10 )$$

The profile buffer Ψ̅(p, t) may be designed as periodic to ensure seamless tiling across all space in the domain. Accordingly, a spatial periodicity parameter L may be introduced to define a normalized projected position p̅∈[0, 1) as follows in equation (11):

$$\overline{p} = ( p - ⌊ p / L ⌋ L ) / L . \qquad Eq . ( 11 )$$

Based on the normalization shown in equation (11), the profile buffer Ψ̅(p, t) may be provided in a reformulated manner as follows in equation (12):

$$\overline{Ψ} ( p , t ) = \overline{Ψ} ( \overline{p} , t ) = {\sum }_{i = 0}^{{N}_{k} - 1} ψ ( {k}_{i} ) cos ( {k}_{i} L \overline{p} - ω ( {k}_{i} ) t ) {k}_{i} Δ k , \qquad Eq . ( 12 )$$

According to equation (12), calculated results of the profile buffer may be stored in a one-dimensional (1D) array by uniformly sampling Nₖ points in an interval [0, 1] as p̅ᵢ. Computation of a j-th entry (or j-th sampling value) in the interval [0, 1] may be achieved via equation (13):

$$\overline{Ψ} ( {\overline{p}}_{j} , t ) = {\sum }_{i = 0}^{{N}_{k} - 1} ψ ( {k}_{i} ) cos ( {k}_{i} L {\overline{p}}_{j} - ω ( {k}_{i} ) t ) {k}_{i} Δ k , \qquad Eq . ( 13 )$$

where p̅ⱼ=(j+0.5)/Nₖ and j=0, 1, 2, . . . , Nₖ−1. Based on lower and upper limits of the wave number, kₘᵢₙ and kₘₐₓ, Δk=(kₘₐₓ−kₘᵢₙ)/Nₖ and kᵢ=kₘᵢₙ+(i+0.5)Δₖ.

Similarly, discretization of η(x, t) may be conducted. For example, the wave direction θ may be discretized into N_{θ} samples equally as 2π/N_{θ} and equation (9) may be revised as follows in equation (14):

$$η ( x , t ) = \frac{2 π A}{{N}_{θ}} {\sum }_{i = 0}^{{N}_{θ} - 1} W ( x , {θ}_{i} ) \overline{Ψ} ( {\hat{k}}_{i} \cdot x , t ) , \qquad Eq . ( 14 )$$

where θᵢ=2πi/N_{θ}, x=(z, x), and \hat{k}ᵢ=(cos θᵢ, sin θᵢ).

Equation (9) or (14) may be solved by numerical algorithms along with specific code implementations. At each time step, two primary tasks can be executed: (i) computing the profile buffer and (ii) performing the height integration. An overview of an example of the algorithm pipeline to solve the equation (9) or (14) is shown according to the pseudocode in Table 2. In an example of processing the pseudocode in Table 2, a CUDA kernel is applied to compute the profile buffer at the beginning of each frame and the computed profile buffer value is sent to OpenGL as a 1D texture via CUDA OpenGL interop.

TABLE 2
Pseudocode of water wave animation

```
t ← 0
Initialization
while t < T
{
  Pre-compute profile buffers
  Integrate water height in vertex shader
  Integrate water normal in fragment shader
  t ← t + Δt
}
```

As shown in Table 2, the pseudocode of a water wave animation includes an initialization step to define a plurality of initial values, a pre-computation step to pre-compute the profile buffers, an integral step to integrate a water height, and an integral step to integrate a water normal. In an example, a shader code is applied to implement the algorithm pipeline shown in Table 2. Thus, the water height integral may be performed at a vertex shader, and the water normal integral may be performed at a fragment shader.

Simulation of the water flow may be initialized through the following steps. Firstly, as both terrain and water are represented by height maps, the height maps are imported to construct a scene. Secondly, a flowmap, which records a fluid velocity field at a stable state, is imported to indicate a wave propagation direction and a wave strength within the simulation domain. Subsequently, several macros (or initial values) are defined to control simulation details. An example of the macros is shown in Table 3.

TABLE 3
Constants defined for simulation of water flow

// physical constants

| | |
|---|---|
| #define PI | 3.14159265359 f |
| #define TAU | 6.28318530718 f |
| #define GRAVITY | 9.81 f |

// profile buffer constants

| | |
|---|---|
| #define DIR_NUM | 32 |
| #define SEG_PER_DIR | 8 |
| #define PB_RESOLUTION | 4096 |
| #define WAVE_DIM | 4 |
| #define FINE_DIR_NUM | (DIR_NUM * SEG_PER_DIR) |

As shown in table 2, the profile buffer is defined as an a 1D texture (or 1D array) with 4096 coordinates according to PB_RESOLUTION. The WAVE_DIM indicates that four channels are used to store displacements and spatial derivatives along vertical and horizontal directions of the water flow.

Profile buffer computation stands as a crucial element in achieving real-time wave animation. Rather than performing intensive summations at all pixels/vertices in the domain at every time step, the profile buffer may be calculated at an onset of each time step. In an example of the calculation of profile buffer, Phillips spectrum in Table 1 is applied as the wave basis ψ(k).

According to the constants defined in Table 3, a 1×4096 texture with four channels (WAVE_DIM=4) is used to define the profile buffer, in which displacements and spatial derivatives along vertical and horizontal directions are stored at the four channels, respectively. Note that the cosine term in equation (10) indicates the vertical displacement of a wave (e.g., Gerstner wave). Displacements and spatial derivatives may be computed according to code shown in Table 4.

As shown in Table 4, the four channels (WAVE_DIM=4) gw [0], gw [1], gw [2], and gw [3] may be computed based on a wave, such as a Gerstner wave. Still referring to Table 4, * gw may indicate a pointer variable gw that stores a memory address of a float value, phase may indicate a phase value of the wave, and k may indicate a wave number of the wave.

TABLE 4
Wave channels based on Gerstner wave

| void gerstner_wave( float * gw, float phase, float k) | |
|---|---|
| { | |
| float s = sin (phase); | |
| float c = cos (phase); | |
| gw [0] = −s ; | // horizontal displacement |
| gw[1] = c; | // vertical displacement |
| gw [2] = −k * c; | // derivative of gw[0] |
| gw [3] = −k * s; | // derivative of gw[1] |

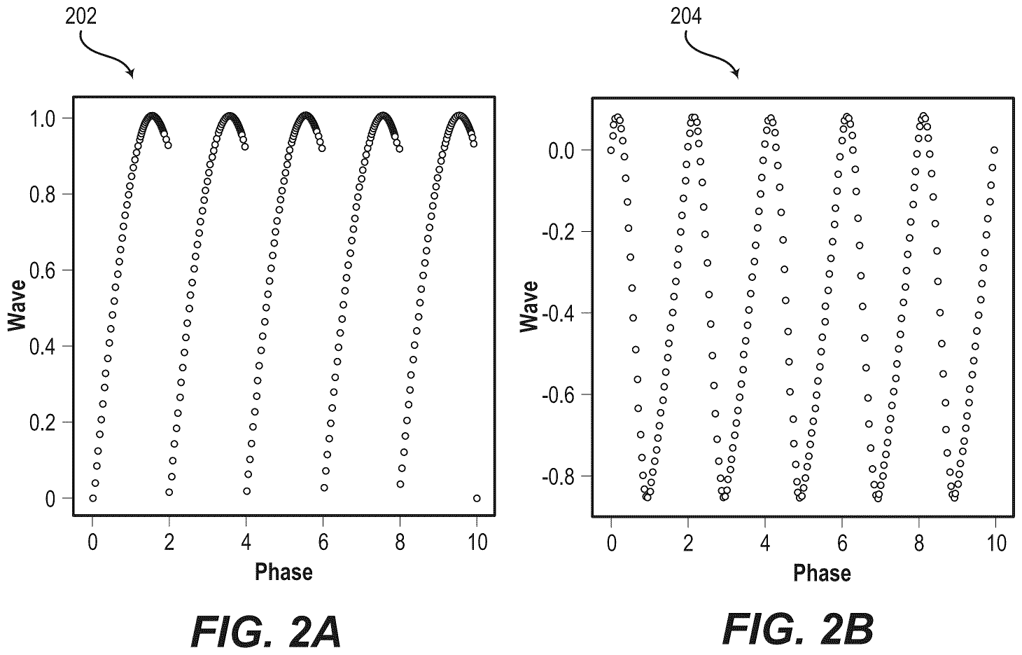

To simulate water waves across large open worlds, the profile buffers may be constructed to be periodic for seamless extension in the world space. However, as shown in FIG. 2A, such a configuration may lead to potential discontinuities near borders of neighboring profile buffers. To resolve the issue of discontinuity, cubic bumps are introduced to interpolate the Gerstner wave with extra points to fix the discontinuity. Equation (15) shows a cubic bump function to interpolate extra points:

$$cubic\_bump ( x ) = \{ \begin{matrix}{x}^{2} ( 2 \vert x \vert - 3 ) + , & if \vert x \vert < 1 , \\ 0 , & otherwise\end{matrix} \qquad Eq . ( 15 )$$

As shown in FIG. 2A, a plot (202) shows a simplified wave without interpolation. Discontinuities arise at a boundary between adjacent profile buffers. As shown in FIG. 2B, a plot (204) shows an interpolated wave in which the discontinuities are resolved.

Table 5 shows an example of Gerstner wave interpolation. As shown in Table 5, a scale s may be applied to adjust a wave propagation speed (or velocity), disper_relation (k, scale) ω(k) may be defined as s\sqrt{gk} according to equation (16), k may indicate the wave number, p may indicate the projected position, L is the spatial periodicity parameter, and WAVE_DIM is equal to 4.

TABLE 5
Gerstner wave interpolation.

```
void interpolate_gerstner_wave (
  real * gw, real k, real p, real L, real scale, real t)
{
    real phase1 = k * p − disper_relation (k, scale) * t;
    real phase2 = k * (p − L) − disper_relation (k, scale) * t;
    real gw1 [WAVE_DIM] ;
    real gw2 [WAVE_DIM] ;
    gerstner_wave (gw1 , phase1, k) ;
    gerstner_wave (gw2, phase2, k) ;
    real weight1 = p / L;
    real weight2 = 1 − weight1 ;
    real cb1 = cubic_bump (weight1) ;
    real cb2 = cubic_bump (weight2) ;
    for (int i = 0; i < WAVE_DIM; ++i)
    {
      gw[i] = cb1 * gw1[i] + cb2 * gw2[i] ;
    }
}
```

Still referring to Table 5, phase 1 is defined as k*p−ω(k)*t. Phase 2 is defined as k*(p−L)−ω(k)*t. A first set of four channels gw1 [WAVE_DIM] is defined to include gw1 [0], gw1 [1], gw1 [2], and gw1 [3]. A second set of four channels gw1 [WAVE_DIM] is defined to include gw2 [0], gw2 [1], gw2 [2], and gw2 [3]. Values of the first set of four channels gw1 [i] are defined based on algorithm gerstner_wave (gw1, phase 1, k) shown in Table 4. Values of the second set of four channels gw2 [i] are defined based on algorithm gerstner_wave (gw2, phase2, k) shown in Table 4. Weight 1 is defined as p/L. Weight 2 is defined as 1−p/L. A first cubic bump value cb1 is defined according to formula cubic_bump (weight1) shown in equation (15). A second cubic bump value cb2 is defined according to formula cubic_bump (weight2) shown in equation (15). A channel value gw [i] is defined as a weighted combination of gw1[i] and gw1[i], such as cb1*gw1[i]+cb2* gw2[i].

Once the channel values gw [i] are defined based on the Gerstner wave interpolation shown in Table 5, the profile buffer shown in equation (10) may be calculated according to code shown in Table 6.

TABLE 6
Profile buffer computation.

```
void compute_profile_buffer
  real* result, real k, real p, real L, real scale, real t)
{
  real waveLength = TAU / k;
  real gw [WAVE_DIM];
  interpolate_gerstner_wave (gw, k, p, L, scale, t );
  real ps = phillips_spectrum (k);
  for (int i = 0; i < WAVE_DIM; ++i)
  {
    Result [i] += waveLength * ps * gw[i];
  }
}
```

As shown in table 6, channel values gw [WAVE_DIM] may be defined according to the algorithm in Table 4. The channel values gw [WAVE_DIM] may further be interpolated according to algorithm interpolate_gerstner_wave (gw, k, p, L, scale, t) shown in Table 5. ps may be defined according to algorithm phillips_spectrum (k) in Table 1. A profile buffer value Result [i] may be defined as Result [i]+waveLength*ps*gw[i]. Thus, the profile buffer is defined as a sum of (i) an initial profile buffer value Result [i] and waveLength*ps*gw[i].

In an aspect, a fast/slow profile tuning is applied in the calculation of the profile buffer to gain finer control over wave behavior. For example, the scale (or the profile scale) s is introduced to adjust the wave propagation speed. The modified dispersion relation ω(k) may then be expressed as follows in equation (16)

$$ω ( k ) = s \sqrt{gk} . \qquad Eq . ( 16 )$$

A larger ω(k) may correspond to a faster wave propagation. Thus, two distinct scale values, s_fast and s_slow, are applied to represent a fast wave propagation and a slow wave propagation, respectively. Accordingly, two set of the profile buffers are calculated based on the two scale values respectively. The profile buffers are then stored in two separate textures: a fast profile buffer field (d_PBf_field_) and a slow profile buffer field (d_PBs_field_).

Once the profile buffers are calculated according to the algorithm in Table 6, integration of height can be conducted. In an aspect, displacement of the water surface vertex is integrated via Gaussian quadrature on the fly in the vertex shader (e.g., performing calculations or modifications to vertex data in real-time) as the data is being processed by the vertex shader. In an example, given a vertex position inPosition at its rest state, a world position of the vertex may be integrated based on the pre-computed profile buffers pbOFieldTex and flowmap layerDataTex.

Integration with Gaussian Quadrature equation (14) represents a classical Riemann sum method designed for numerical integration. However, it necessitates a greater number of summations to attain high precision.

In an aspect of the disclosure, Gaussian quadrature is applied to provide an exact result for polynomials of degree 2Nᵢₙₜ−1 or lower through a suitable selection of nodes Pᵢ and weights αᵢ for i=0, . . . , Nᵢₙₜ−1. Gaussian quadrature can be applied without modification when original limits of integration are [−1, 1]. In this scenario, the positions of integration points P₀, P₁, . . . , P_{N}_{ᵢₙₜ}−1 as well as associated weights of the integration points α₀, α₁, . . . , α_{N}_{ᵢₙₜ}−1 can be pre-computed, without requiring knowledge of the specific expression of the integrand. Based on the pre-computed integration points and the associated weights, the original Riemann sum in equation (14) may be transformed into a new form as follows in equation (17):

$$η ( x , t ) = {s}_{G} A {\sum }_{i = 0}^{{N}_{int} - 1} {α}_{i} W ( x , {θ}_{i} ) \overline{Ψ} ( z cos {θ}_{i} + x sin {θ}_{i} , t ) , \qquad Eq . ( 17 )$$

where θᵢ=πPᵢ+π,

$${s}_{G} = \frac{2 π}{2} = π$$

is a scaling factor. When the limits of integration change to a custom range, the integration may require scaling, and the scaling factor may be simply a ratio of the actual limit length to the original limit length, which is 2 for the range [−1, 1]. In an example of the wave height calculation, 32 points of integration are utilized.

Examples of the pre-computed Gaussian quadrature point positions and the associated weights are provided in Table 7. As shown in Table 7, each node Pᵢ corresponds to a respective weight αᵢ.

TABLE 7
Gaussian quadrature points and weights

| | |
|---|---|
| int nnodes = 32; | |
| float nodes[32] = { | |
| −0.9972638618494816 f , | −0.9856115115452684 f , |
| −0.9647622555875064 f , | −0.9349060759377397 f , |
| −0.8963211557660522 f , | −0.84936761373257 f , |
| −0.7944837959679424 f , | −0.7321821187402897 f , |
| −0.6630442669302152 f , | −0.5877157572407623 f , |
| −0.5068999089322294 f , | −0.42135127613063533 f , |
| −0.33186860228212767f | −0.23928736225213706 f , |
| −0.1444719615827965 f , | −0.04830766568773831 f , |
| 0.04830766568773831 f , | 0.1444719615827965 f , |
| 0.23928736225213706 f , | 0.33186860228212767 f , |
| 0.42135127613063533 f , | 0.5068999089322294 f , |
| 0.5877157572407623 f , | 0.6630442669302152 f , |
| 0.7321821187402897 f , | 0.7944837959679424 f , |
| 0.84936761373257 f , | 0.8963211557660522 f , |
| 0.9349060759377397 f , | 0.9647622555875064 f , |
| 0.9856115115452684 f , | 0.9972638618494816 f } ; |
| float weights [32] = { | |
| 0.007018610009469298 f , | 0.016274394730905965 f , |
| 0.025392065309262427 f , | 0.034273862913021626 f , |
| 0.042835898022226426 f , | 0.050998059262376244 f , |
| 0.058684093478535704 f , | 0.06582222277636175 f , |
| 0.07234579410884845 f , | 0.07819389578707031 f , |
| 0.08331192422694685 f , | 0.08765209300440391 f , |
| 0.09117387869576386 f , | 0.09384439908080457 f , |

Further, each entry in equation (17) at the vertex position inPosition can be computed. Assuming a primary angle θₚ=arctan(vₓ/v_{z}) has been computed, the weight W(x, θᵢ) may be calculated as follows in Table 8. As shown in Table 8, the weight W(x, θᵢ) may be defined as 1−min(C, min(diffa, TAU−diffa)/C. diffa is equal to |θₚ−θᵢ|. θᵢ may indicate a wave direction of a water wave at the position x.

TABLE 8
Weight calculation.

float diffa = abs(theta_p − theta_i);
float W= 1 − min (C, min (diffa , TAU − diffa))/C;

Still referring to equation (17), Ψ̅(z cos θᵢ+x sin θᵢt) may indicate at in-situ profile buffer value. The in-situ profile buffer value may be determined by interpolation of the pre-computed Ψ̅(p̅ ⱼ, t) according to Table 6. For example, for a water wave at a position x=(z, x), z cos θᵢ+x sin θᵢt may be calculated. Based on the value of z cos θᵢ+x sin θᵢ, Ψ̅(z cos θᵢ+x sin θᵢ, t) may be determined by interpolating two adjacent pre-computed profile buffers Ψ̅(p̅ ₁, t) and Ψ̅(p̅ ₂, t), where z cos θᵢ+x sin θᵢ is positioned between coordinates p̅ ₁ and p̅ ₂ in the 1D texture (or 1D array).

According to the calculated W(x, θᵢ) and Ψ̅(z cos θᵢ+x sin θᵢ, t), the water height η(x, t) in equation (17) can be obtained.

In an aspect of the disclosure, blending two profiles (e.g., fast profile buffer and slow profile buffer) may enhance the portrayal of wave propagation details. Depending on the strength of velocity, a weight function w=min (1, |v|) may be defined to ensure that the fast profile buffer occupies a larger proportion as the magnitude of the current velocity increases. The profile buffer may include four components. The four components may be arranged in an original order, such as an order including the horizontal and vertical displacements of both the slow and fast profile buffers. A blended profile buffer can be represented as follows in Table 9.

TABLE 9
A blended profile buffer

vec2 pbb = (1 . f − scale ) * pb . xy + scale * pb . wz;

As shown in Table 9, the blended profile buffer is equal to (1−scale)*pb.xy+scale*pb.wz. The scale may indicate a weight factor, and pb.xy and pb.wz may represent the displacement parts of the slow and fast profile buffer, respectively.

In an aspect of the disclosure, adaptive limits of integration may be applied. According to an assumption (or predefined condition), waves may only propagate within a range near the primary angle defined in equation (4). When the range is expanded, more waves in different directions may be blended together. When the range is narrowed, waves appear to move predominantly in one direction. In an example shown in FIG. 1, a narrow range can lead to artificial constructive patterns. Conversely, an excessively wide range may obscure the recognition of wave direction, resulting in smoothed-out wave propagation. The angle range of wave propagation may be dynamically adjusted based on a maximum difference of a velocity direction between each cell (e.g., a center of the cell) and neighboring cells (or subregions) in the domain. The maximum difference may serve as an indicator of a local velocity variation.

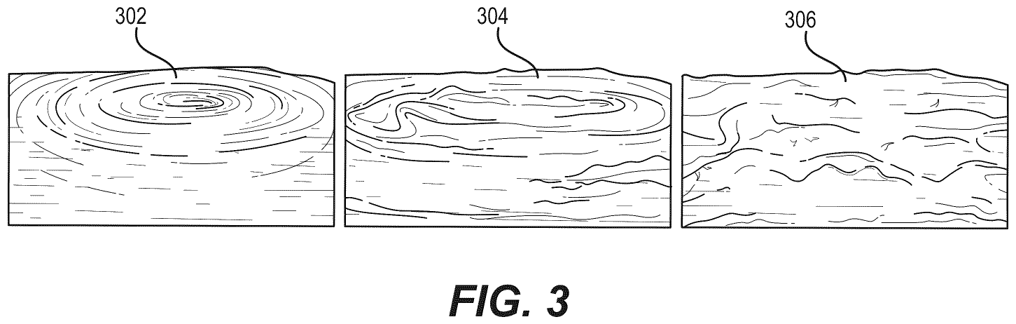

FIG. 3 shows an example of adaptive limits of integration. As shown in FIG. 3, a flowmap characterized by an uniform strength and a radial outward direction from a central point is evaluated. Images (302), (304), and (306) show a fixed small integration range, an adaptive integration range, and a fixed large integration range, respectively. Prominent artificial patterns are discernible on the image (302). The wave propagation appears excessively smooth, hindering clear recognition on the image (306). The image (304) based on the adaptive integration range exemplifies the outward movement of waves with realistic turbulence.

Table 10 shows pseudocode for a local velocity variation computation between a current cell (or current subregion) and a neighboring cell of the current cell in the domain.

TABLE 10
Pseudocode for local velocity variation computation

```
for each cell i in simulation domain
{
  Mᵢ ← Neighboring cells of cell i
  θᵢ ← arctan(υᵢ/uᵢ)
  Δθₘₐₓ ← 0
  for each cell j ∈ Mᵢ
  {
    ${θ}_{i} ← arctan ( \frac{{υ}_{j}}{{u}_{j}} )$
    Δθ ← ||θⱼ − θᵢ||
    Δθ ← min (Δθ, 2π − Δθ)
    If Δθ > Δθₘₐₓ
    {
      Δθₘₐₓ ← Δθ}
    }
  }
}
```

As shown in Table 10, a plurality of cells (or subregions) in a simulation domain for water simulation is defined. A water direction θᵢ for a current cell i is defined as arctan(υᵢ/uᵢ). υᵢ and uᵢ are two velocity components of a water wave in the cell i. Mᵢ is defined as a neighboring cell group of the current cell i. For a neighboring cell j, a water direction θⱼ is defined as arctan(υⱼ/uⱼ). A water direction difference Δθ between the current cell i and the neighboring cell j is defined as ∥θⱼ−θᵢ∥. Further, Δθ is replaced with min(Δθ, 2π−Δθ). If Δθ is larger than a preset value (e.g., 0) of Δθₘₐₓ, Δθₘₐₓ is replaced with Δθ.

When the primary angles (e.g., θᵢ and θⱼ) are calculated and the maximum difference (e.g., Δθₘₐₓ) in velocity direction is precomputed, the limits of integration associated with non-zero weights can be determined. According to an assumption (or predefined condition), within a given area, if the local velocity variation is significant, a larger range of integration angles is required to accurately represent the varying wave propagation directions. As previously mentioned with respect to Table 3, all possible propagation directions of a waterflow may be partitioned from the range [0, 2π] into DIR_NUM segments. In an example of Table 3, DIR_NUM is 32. Each segment is further subdivided into SEG_PER_DIR pieces, such as 8 pieces, resulting in a total of DIR_NUM*SEG_PER_DIR subdivisions across the full 2π range. Subsequently, which subdivisions correspond to non-zero weights may be determined. The half-width of the non-zero weight area, denoted as C, can be calculated in Table 11.

Table 11 shows an example of computation of adaptive limits of integration. As shown in Table 11, delta_mag is defined as Δθₘₐₓ calculated in Table 10. C is defined as (SEG_HW)/(FINE_DIR_NUM)*TAU. According to Table 10, each cell i in the simulation domain has a respective Δθₘₐₓ. Thus, according to Table 11, each cell i in the simulation domain corresponds to a respective C.

TABLE 11
Compute adaptive limits of integration.

int INT_NUM = min(16 ,4+ int (500* delta_mag /TAU) ) ;
int SEG HW = SEG_PER_DIR*INT_NUM;
float C = float (SEG_HW)/ float (FINE_DIR_NUM)*TAU ;

When the water height is calculated according to algorithms described in Tables 7-11, calculation of a surface normal can be conducted. Surface normal calculation is can be used to visually represent a surface shape of waves in rendering. In an aspect, the surface of a normal height map associated with a waterflow may be computed via

$$n = \frac{{T}_{z} \times {T}_{x}}{‖ {T}_{z} \times {T}_{x} ‖} ,$$

where T_{z} and Tₓ are gradient vectors in a z-direction and a x-direction (in other words, the horizontal directions in OpenGL), respectively. Given the integration process for the wave height from equation (9), a gradient of the height map concerning the horizontal position (e.g., in the z-direction and the x-direction) can be provided according to equations (18) and (19):

$${∇}_{x} η ( x , t ) = {∇}_{x} {\int }_{0}^{2 π} AW ( x , θ ) \overline{Ψ} ( p , t ) d θ \qquad Eq . ( 18 )$$

$$= {\int }_{0}^{2 π} {∇}_{x} ( AW ( x , θ ) ) \overline{Ψ} ( p , t ) d θ + {\int }_{0}^{2 π} AW ( x , θ ) {∇}_{x} ( \overline{Ψ} ( p , t ) ) d θ , \qquad Eq . ( 19 )$$

The first term in equation (19) may be omitted because the flowmap maintains continuity in the domain space, indicating that the derivative ∇ₓ(AW(x, θ)) tends to be close to 0. Accordingly, equation (19) is finalized for calculating height gradients as follows in equation (20):

$${∇}_{x} η ( x , t ) = {\int }_{0}^{2 π} AW ( x , θ ) {∇}_{x} \overline{Ψ} ( p , t ) d θ . \qquad Eq . ( 20 )$$

Calculation of the gradient vectors T_{z} and Tₓ can be executed as follows in equations (21) and (22) respectively:

$${T}_{z} = ( 1 , 0 , {( {∇}_{x} η )}_{z} ) ⇒ {T}_{z} = {T}_{z} / ‖ {T}_{z} ‖ , \qquad Eq . ( 21 )$$

$${T}_{x} = ( 1 , 0 , {( {∇}_{x} η )}_{x} ) ⇒ {T}_{x} = {T}_{x} / ‖ {T}_{x} ‖ . \qquad Eq . ( 22 )$$

where (∇ₓη)_{z} indicates a component of the height gradient ∇ₓη(x, t) at the z direction and (∇ₓη)ₓ indicates a component of the height gradient ∇ₓη(x, t) at the x direction.

The gradient vectors calculated in equations (21) and (22) may only be directed to the vertical displacement rather than the horizontal displacement. In an aspect shown in Table 12, a normal integration procedure may be executed within a fragment shader, and the pipeline shown in Table 12 may resemble the pipeline of height integration, albeit with an additional step of integrating T_{z} and Tₓ and subsequently employing a cross-product operation to derive the normal vector.

TABLE 12
Normal integration.

. . . // init setup
vec3 tz = vec3(0 . f , 0 . f , 1 . f) ;
vec3 tx = vec3(1 . f , 0 . f , 0 . f) ;
for ( int sid = 0 ; sid < nnodes ; ++sid)
{
. . . // normal integration
}
vec3 newNormal = cross (tz , tx) ;
newNormal = normalize ( newNormal) ;

As shown in Table 12, initial values (0, 0, 1) and (1, 0, 0) are assigned to T_{z} and Tₓ respectively. Gradient vectors T_{z} and Tₓ can further be calculated, such as according to equations (21) and (22). A cross-product operation (e.g., T_{z}×Tₓ) is conducted to derive the normal vector in y-direction according to newNormal=cross (tz, tx). Further, the normal vector is normalized according to newNormal=normalize (newNormal).

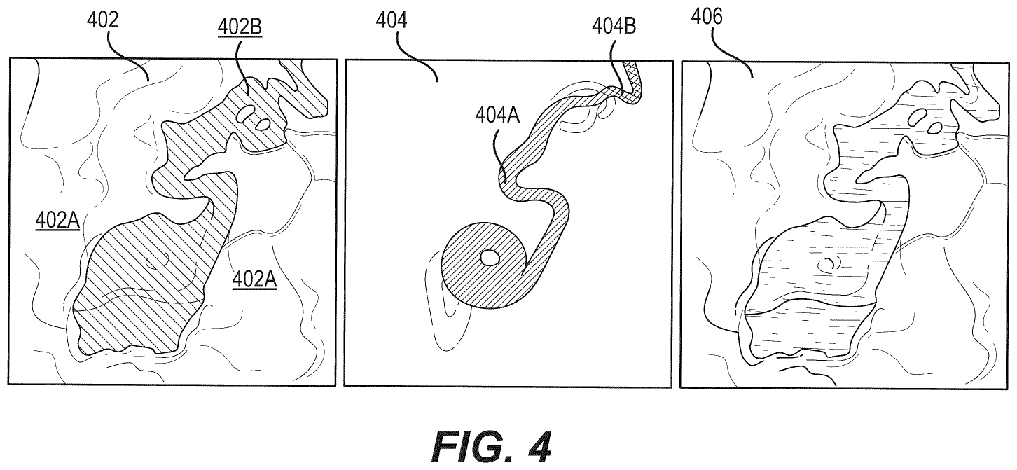

Aspects of the disclosure demonstrate effectiveness of water flow simulation. For example, a profiling time can be significantly reduced through the implementation of Gaussian quadrature. Adaptive limits of integration is shown to contribute to overall quality improvement. Blended two profile buffers enhances the depiction of wave movements. FIG. 4 shows a custom-designed map featuring a river scene for all demonstrations and comparisons between the methods of the present disclosure and the related examples. All tests were conducted using a 4.0 GHz AMD Ryzen Threadripper PRO 5955WX 16-Cores processor paired with an NVIDIA Geforce RTX 4080 GPU with 16 GB of memory.

As shown in FIG. 4, an image (402) shows a terrain height map. In the image (402), areas (402A) indicate higher elevations than areas (402B). An image (404) shows a flowmap. Shades (404A) in the image (404) represent lower velocity magnitudes, and the shades (404B) represent higher velocity magnitudes. Further, an image (406) provides a top view of the rendered scene.

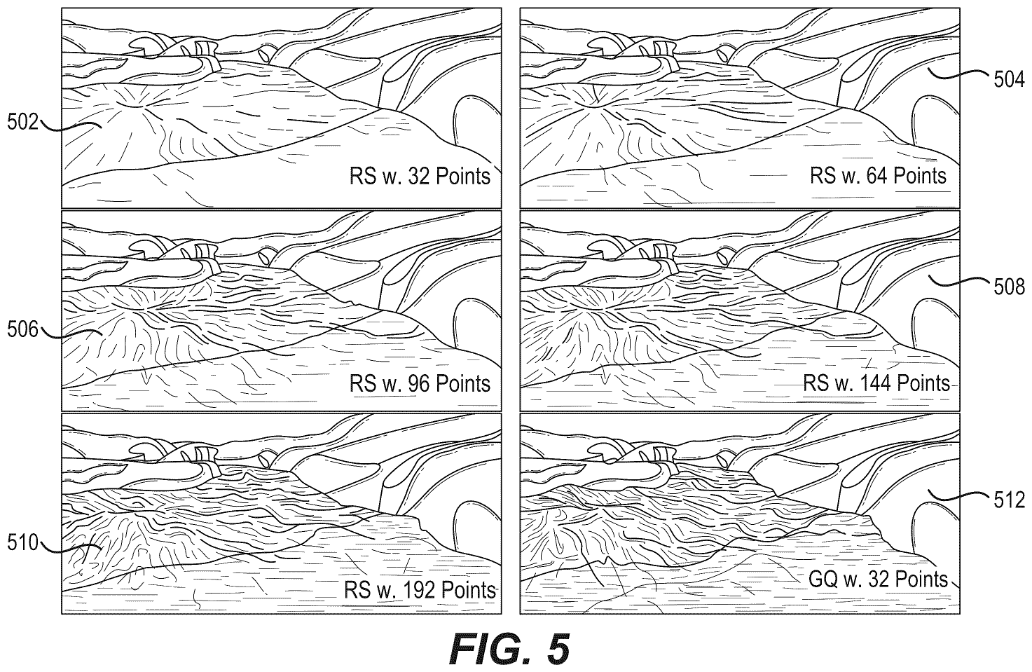

FIG. 5 shows an example of performance comparison between Riemann sum (RS) and the disclosed method using Gaussian quadrature (GQ). As shown in FIG. 5, water flow simulation images (or images) (502), (504), (506), (508), and (510) were generated by RS with 32, 64, 96, 144, and 192 integration points respectively, and a water flow simulation image (512) was generated by GQ with 32 integration points. According to the comparisons, Gaussian quadrature with 32 integration points achieves visual results comparable to those of Riemann sum with 192 integration points. Notably, the achievement of Gaussian quadrature with 32 integration points is accompanied by a significant reduction in profiling time by 63%, highlighting the efficiency of the disclosed method of the present disclosure. Moreover, to achieve a similar profiling time, Riemann sum is constrained to using only 32 points, resulting in a compromised visual appearance. The trade-off underscores the superiority of Gaussian quadrature in balancing computational efficiency with visual quality.

According to comparisons between Riemann sum (RS) with different numbers of integration points (e.g., 32, 64, 96, 144, 192) and Gaussian quadrature (GQ) in FIG. 5, the Riemann sum exhibits noticeable unnatural patterns with an insufficient number of integration points 32. Furthermore, the Riemann sum method requires approximately six times the number of integration points to attain comparable results in visual fidelity and detail.

Table 13 shows performance comparisons between the Riemann sum with different numbers of integration points and the Gaussian quadrature. As shown in FIG. 5, although the Reimann sum at 32 integration points show a shorter runtime, the water flow rendered unnatural patterns.

TABLE 13
Comparison between Riemann sum and Gaussian quadrature

| Integration Method | # integration points | Runtime (ms) |
|---|---|---|
| Riemann sum | 32 | 3.01 |
| | 64 | 4.65 |
| | 96 | 4.91 |
| | 144 | 6.46 |
| | 192 | 8.26 |
| Gaussian quadrature | 32 | 3.03 |

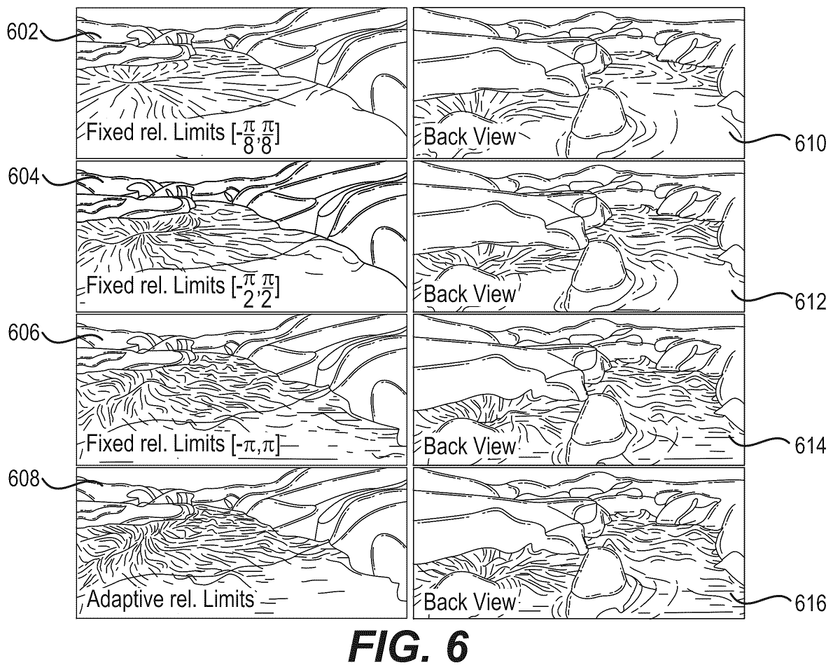

FIG. 6 shows an example of the impact on visual appearance by applying adaptive limits of integration. During per-pixel normal integration and per-vertex height integration, the flowmap may indicate a local flow orientation. Thus, the maximum amplitude strength is set to appear along the direction (e.g., the local flow orientation). The amplitude strength linearly diminishes as the direction deviates further from the central orientation (e.g., the local flow orientation). The proposed adaptive strategy of the present disclosure may determine a maximum non-zero amplitude range, based on variation in the local flowmap.

As shown in FIG. 6, water flow simulation images (602), (604), and (606) are generated based on fixed limits of integration in ranges of

$$[ - \frac{π}{8} , \frac{π}{8} ] , [ - \frac{π}{2} , \frac{π}{2} ] ,$$

and [-π, π] respectively. Images (610), (612), and (614) are back views of the simulated water flow corresponding to the images (602), (604), and (606) respectively. FIG. 6 also shows a water flow simulation image (608) based on adaptive integration limits. A back view image (616) is provided for the simulated water flow corresponding to the image (608). According to the comparison between the adaptive integration limits and the fixed limits of integration (e.g.,

$$[ - \frac{π}{8} , \frac{π}{8} ] , [ - \frac{π}{2} , \frac{π}{2} ] ,$$

[-π, π], a small integration range (e.g., image (602) shows merged anomalous constructive patterns, while a large range (e.g., image (606)) results in overly smoothed wave movement and vague wave propagation direction. Adaptive integration limits effectively mitigate observable constructive structures and enhance the clarity of wave propagation direction.

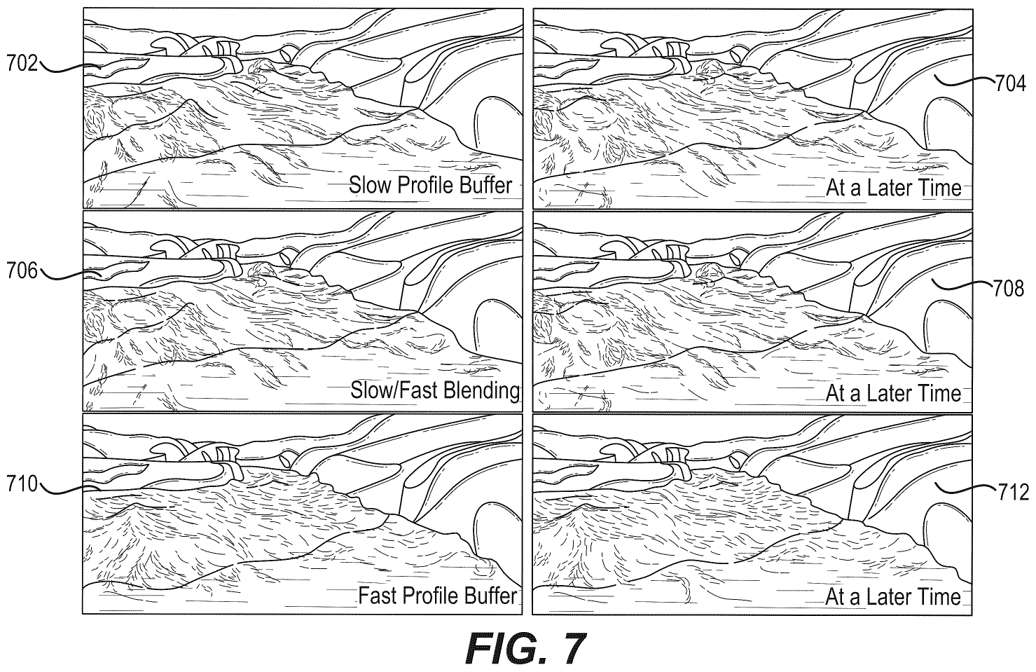

FIG. 7 shows examples of different wave behaviors characterized by a fast propagation speed, a slow propagation speed, and a blending of the fast propagation speed and the slow propagation speed. As shown in FIG. 7, a water flow with the fast propagation speed is shown in images (710) and (712), a water flow with the slow propagation speed is shown in images (702) and (704), and a water flow with the blending of the fast propagation speed and the slow propagation speed is shown in images (706) and (708).

Aspects of the disclosure provide a real-time framework for simulating waves in open-world scenarios. Various benefits are demonstrated in the methods of the present disclosure. For example, the profile buffer introduced in the disclosed methods can more efficiently transforms computationally-intensive integration tasks into reusable texture fetching operations. The applied Gaussian quadrature achieve significant speed improvements while maintaining visual quality. Furthermore, the adaptive limits of integration applied in the disclosed methods can achieve diverse visual effects, and the blending of profile buffers can enrich wave propagation details.

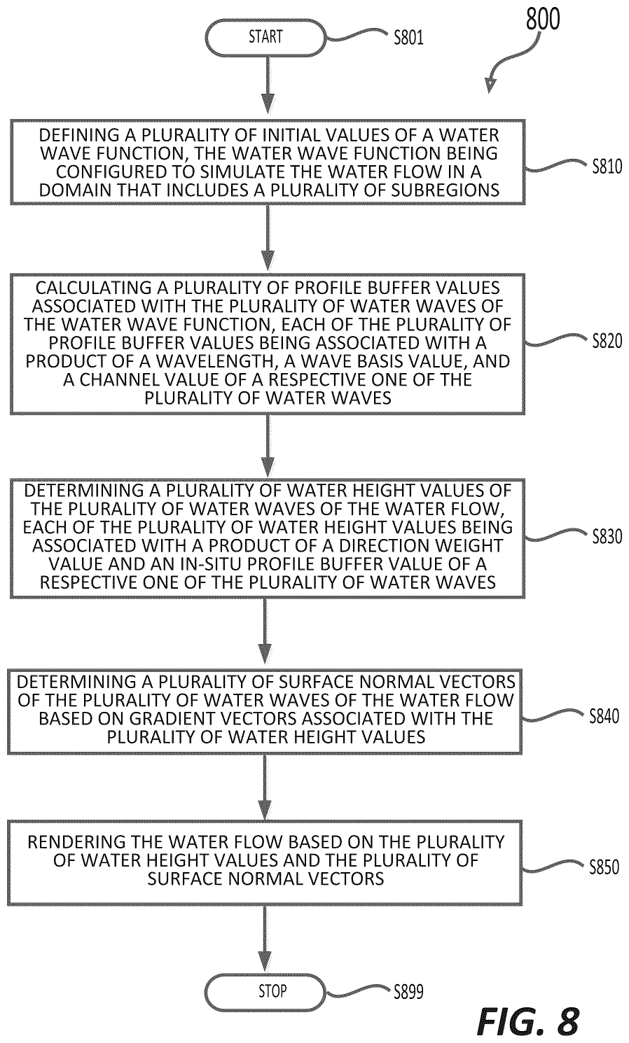

FIG. 8 shows a flow chart outlining a process (800) according to an aspect of the disclosure. In some aspects, the process (800) is implemented in software instructions, thus when the processing circuitry executes the software instructions, the processing circuitry performs the process (800). The process starts at (S801) and proceeds to (S810).

At (S810), a plurality of initial values of a water wave function is defined. The water wave function is configured to simulate the water flow in a domain that includes a plurality of subregions.

At (S820), a plurality of profile buffer values associated with the plurality of water waves of the water wave function is calculated. Each of the plurality of profile buffer values is associated with a product of a wavelength, a wave basis value, and a channel value of a respective one of the plurality of water waves.

At (S830), a plurality of water height values of the plurality of water waves of the water flow is determined. Each of the plurality of water height values is associated with a product of a direction weight value and an in-situ profile buffer value of a respective one of the plurality of water waves.

At (S840), a plurality of surface normal vectors of the plurality of water waves of the water flow is determined based on gradient vectors associated with the plurality of water height values.

At (S850), the water flow is rendered based on the plurality of water height values and the plurality of surface normal vectors.

In an aspect, the channel value of the respective one of the plurality of water waves includes one of a first channel value indicating a horizontal displacement of the respective one of the plurality of water waves, a second channel value indicating a vertical displacement of the respective one of the plurality of water waves, a third channel value indicating a derivative of the first channel value, and a fourth channel value indicating a derivative of the second channel value.

In an aspect, a first phase value of the water flow is determined based on (i) a product of a first wave number and a projected position of the respective one of the plurality of water waves in the domain minus (ii) a product of an angular frequency associated with the first wave number and a first time moment. A second phase value of the water flow is determined based on (i) a product of the first wave number and an updated projected position minus (ii) the product of the angular frequency associated with the first wave number and the first time moment. The updated projected position is equal to the projected position minus a spatial periodicity parameter. A first initial channel value is determined based on the first phase value and a second initial channel value is determined based on the second phase value. A first weight value is determined based on a ratio of the projected position to the spatial periodicity parameter and a second weight value is determined as one minus the first weight value. A first cubic bump value is determined based on the first weight value and a second cubic bump value is determined based on the second weight value. A first channel value is determined as a sum of (i) a product of the first weight value and the first initial channel value and (ii) a product of the second weight value and the second initial channel value.

In an aspect, the first cubic bump value is based on x²(2|x|−3)+1 when an absolute value of the x is less than 1. The x is the first weight value.

In an aspect, a first wavelength is determined as a ratio of 2π to the first wave number. A first one of the plurality of profile buffer values is determined based on a product of the first wavelength, a wave basis value defined according to a Phillips spectrum value associated with the first wave number, and the first channel value.

In an aspect, the plurality of profile buffer values includes (i) a first subset that is calculated based on a first group of angular frequencies associated with a first wave propagation velocity of the water flow and (ii) a second subset that is calculated based on a second group of angular frequencies associated with a second wave propagation velocity of the water flow.

In an aspect, a first direction weight value is determined based on (i) a coordinate of a first position in a first subregion of the plurality of subregions of the domain and (ii) a wave direction of one of the plurality of water waves at the first position. A first in-situ profile buffer value is determined based on an interpolated value between two adjacent profile buffer values of the first in-situ profile buffer value. A first water height value of the plurality of water height values is determined based on a product of the first direction weight value and the first in-situ profile buffer value.

In an aspect, the first direction weight value is equal to 1 minus min (C, min (diffa, TAU−diffa))/C. The diffa is equal to abs (theta_p−theta_i). The theta_p is a primary wave direction of the first subregion and the theta_i is the wave direction of the one of the plurality of water waves at the first position. C is a constant and TAU is equal to 2π.

In an aspect, a first water height value of the plurality of water height values is determined based on a weighted combination of (i) a first subset water height value calculated according to a first one of the first subset of the plurality of profile buffer values and (ii) a second subset water height value calculated according to a first one of the second subset of the plurality of profile buffer values.

In an aspect, the C is defined as (SEG_HW)/(FINE_DIR_NUM)*TAU. SEG_HW is equal to a product of SEG_PER_DIR and INT_NUM. INT_NUM is based on a maximum wave direction difference of wave direction differences between the plurality of water waves in the first subregion and neighboring subregions of the first subregion in the plurality of subregions. FINE_DIR_NUM and SEG_PER_DIR are included in the plurality of initial values.

In an aspect, the wave direction of the one of the plurality of water waves at the first position in the first subregion is determined based on an arctangent of a ratio of a wave velocity of the one of the plurality of water waves in a first direction to the wave velocity of the one of the plurality of water waves in a second direction. A wave direction of one of the plurality of water waves at an adjacent subregion of the first subregion in the plurality of subregions is determined. A wave direction difference between the wave direction at the first position and the wave direction at the adjacent subregion is determined. A minimum value between (i) the wave direction difference and (ii) two x minus the wave direction difference is determined. The maximum wave direction difference is determined as the minimum value of (i) the wave direction difference and (ii) two x minus the wave direction difference when the minimum value is larger than a preset value of the maximum wave direction difference.

In an aspect, a first gradient vector associated with a first water height value of the plurality of water height values is determined. A first component of the first gradient vector in a first direction and a second component of the first gradient vector in a second direction are determined. A first normal vector is determined as a cross product of the first component of the first gradient vector and the second component of the first gradient vector. A first surface normal vector of the plurality of surface normal vectors is determined based on a normalization of the first normal vector.

Then, the process proceeds to (S899) and terminates.

The process (800) can be suitably adapted. Step(s) in the process (800) can be modified and/or omitted. Additional step(s) can be added. Any suitable order of implementation can be used.

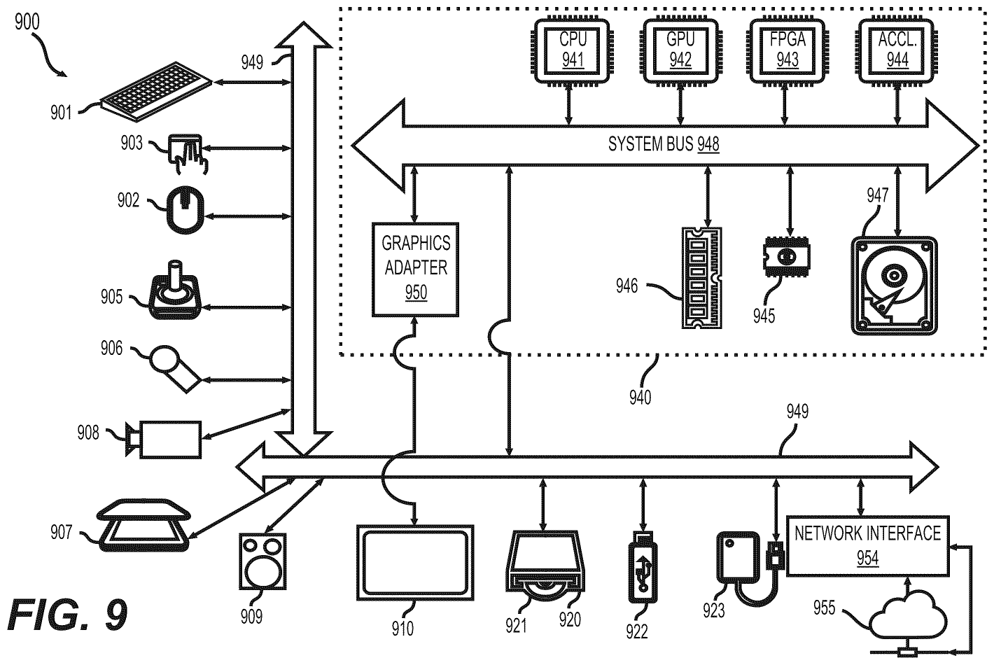

The techniques described above, can be implemented as computer software using computer-readable instructions and physically stored in one or more computer-readable media. For example, FIG. 9 shows a computer system (900) suitable for implementing certain aspects of the disclosed subject matter.

The computer software can be coded using any suitable machine code or computer language, that may be subject to assembly, compilation, linking, or like mechanisms to create code comprising instructions that can be executed directly, or through interpretation, micro-code execution, and the like, by one or more computer central processing units (CPUs), Graphics Processing Units (GPUs), and the like.

The instructions can be executed on various types of computers or components thereof, including, for example, personal computers, tablet computers, servers, smartphones, gaming devices, internet of things devices, and the like.

The components shown in FIG. 9 for computer system (900) are examples and are not intended to suggest any limitation as to the scope of use or functionality of the computer software implementing aspects of the present disclosure. Neither should the configuration of components be interpreted as having any dependency or requirement relating to any one or combination of components illustrated in the example aspect of computer system (900).

Computer system (900) may include certain human interface input devices. Such a human interface input device may be responsive to input by one or more human users through, for example, tactile input (such as: keystrokes, swipes, data glove movements), audio input (such as: voice, clapping), visual input (such as: gestures), olfactory input (not depicted). The human interface devices can also be used to capture certain media not necessarily directly related to conscious input by a human, such as audio (such as: speech, music, ambient sound), images (such as: scanned images, photographic images obtain from a still image camera), video (such as two-dimensional video, three-dimensional video including stereoscopic video).

Input human interface devices may include one or more of (only one of each depicted): keyboard (901), mouse (902), trackpad (903), touch screen (910), data-glove (not shown), joystick (905), microphone (906), scanner (907), camera (908).

Computer system (900) may also include certain human interface output devices. Such human interface output devices may be stimulating the senses of one or more human users through, for example, tactile output, sound, light, and smell/taste. Such human interface output devices may include tactile output devices (for example tactile feedback by the touch-screen (910), data-glove (not shown), or joystick (905), but there can also be tactile feedback devices that do not serve as input devices), audio output devices (such as: speakers (909), headphones (not depicted)), visual output devices (such as screens (910) to include CRT screens, LCD screens, plasma screens, OLED screens, each with or without touch-screen input capability, each with or without tactile feedback capability-some of which may be capable to output two dimensional visual output or more than three dimensional output through means such as stereographic output; virtual-reality glasses (not depicted), holographic displays and smoke tanks (not depicted)), and printers (not depicted).

Computer system (900) can also include human accessible storage devices and their associated media such as optical media including CD/DVD ROM/RW (920) with CD/DVD or the like media (921), thumb-drive (922), removable hard drive or solid state drive (923), legacy magnetic media such as tape and floppy disc (not depicted), specialized ROM/ASIC/PLD based devices such as security dongles (not depicted), and the like.

Those skilled in the art should also understand that term “computer readable media” as used in connection with the presently disclosed subject matter does not encompass transmission media, carrier waves, or other transitory signals.

Computer system (900) can also include an interface (954) to one or more communication networks (955). Networks can for example be wireless, wireline, optical. Networks can further be local, wide-area, metropolitan, vehicular and industrial, real-time, delay-tolerant, and so on. Examples of networks include local area networks such as Ethernet, wireless LANs, cellular networks to include GSM, 3G, 4G, 5G, LTE and the like, TV wireline or wireless wide area digital networks to include cable TV, satellite TV, and terrestrial broadcast TV, vehicular and industrial to include CANBus, and so forth. Certain networks commonly require external network interface adapters that attached to certain general purpose data ports or peripheral buses (949) (such as, for example USB ports of the computer system (900)); others are commonly integrated into the core of the computer system (900) by attachment to a system bus as described below (for example Ethernet interface into a PC computer system or cellular network interface into a smartphone computer system). Using any of these networks, computer system (900) can communicate with other entities. Such communication can be uni-directional, receive only (for example, broadcast TV), uni-directional send-only (for example CANbus to certain CANbus devices), or bi-directional, for example to other computer systems using local or wide area digital networks. Certain protocols and protocol stacks can be used on each of those networks and network interfaces as described above.

Aforementioned human interface devices, human-accessible storage devices, and network interfaces can be attached to a core (940) of the computer system (900).

The core (940) can include one or more Central Processing Units (CPU) (941), Graphics Processing Units (GPU) (942), specialized programmable processing units in the form of Field Programmable Gate Areas (FPGA) (943), hardware accelerators for certain tasks (944), graphics adapters (950), and so forth. These devices, along with Read-only memory (ROM) (945), Random-access memory (946), internal mass storage such as internal non-user accessible hard drives, SSDs, and the like (947), may be connected through a system bus (948). In some computer systems, the system bus (948) can be accessible in the form of one or more physical plugs to enable extensions by additional CPUs, GPU, and the like. The peripheral devices can be attached either directly to the core's system bus (948), or through a peripheral bus (949). In an example, the screen (910) can be connected to the graphics adapter (950). Architectures for a peripheral bus include PCI, USB, and the like.

CPUs (941), GPUs (942), FPGAs (943), and accelerators (944) can execute certain instructions that, in combination, can make up the aforementioned computer code. That computer code can be stored in ROM (945) or RAM (946). Transitional data can also be stored in RAM (946), whereas permanent data can be stored for example, in the internal mass storage (947). Fast storage and retrieve to any of the memory devices can be enabled through the use of cache memory, that can be closely associated with one or more CPU (941), GPU (942), mass storage (947), ROM (945), RAM (946), and the like.

The computer readable media can have computer code thereon for performing various computer-implemented operations. The media and computer code can be those specially designed and constructed for the purposes of the present disclosure, or they can be of the kind well known and available to those having skill in the computer software arts.

As an example and not by way of limitation, the computer system having architecture (900), and specifically the core (940) can provide functionality as a result of processor(s) (including CPUs, GPUs, FPGA, accelerators, and the like) executing software embodied in one or more tangible, computer-readable media. Such computer-readable media can be media associated with user-accessible mass storage as introduced above, as well as certain storage of the core (940) that are of non-transitory nature, such as core-internal mass storage (947) or ROM (945). The software implementing various aspects of the present disclosure can be stored in such devices and executed by core (940). A computer-readable medium can include one or more memory devices or chips, according to particular needs. The software can cause the core (940) and specifically the processors therein (including CPU, GPU, FPGA, and the like) to execute particular processes or particular parts of particular processes described herein, including defining data structures stored in RAM (946) and modifying such data structures according to the processes defined by the software. In addition or as an alternative, the computer system can provide functionality as a result of logic hardwired or otherwise embodied in a circuit (for example: accelerator (944)), which can operate in place of or together with software to execute particular processes or particular parts of particular processes described herein. Reference to software can encompass logic, and vice versa, where appropriate. Reference to a computer-readable media can encompass a circuit (such as an integrated circuit (IC)) storing software for execution, a circuit embodying logic for execution, or both, where appropriate. The present disclosure encompasses any suitable combination of hardware and software.

The use of “at least one of” or “one of” in the disclosure is intended to include any one or a combination of the recited elements. For example, references to at least one of A, B, or C; at least one of A, B, and C; at least one of A, B, and/or C; and at least one of A to C are intended to include only A, only B, only C or any combination thereof. References to one of A or B and one of A and B are intended to include A or B or (A and B). The use of “one of” does not preclude any combination of the recited elements when applicable, such as when the elements are not mutually exclusive.

While this disclosure has described several examples of aspects, there are alterations, permutations, and various substitute equivalents, which fall within the scope of the disclosure. It will thus be appreciated that those skilled in the art will be able to devise numerous systems and methods which, although not explicitly shown or described herein, embody the principles of the disclosure and are thus within the spirit and scope thereof.

What is claimed is:

1. A method of simulating water flow with a plurality of water waves, the method comprising:
defining a plurality of initial values of a water wave function, the water wave function being configured to simulate the water flow in a domain that includes a plurality of subregions;
calculating a plurality of profile buffer values associated with the plurality of water waves of the water wave function, each of the plurality of profile buffer values being associated with a product of a wavelength, a wave basis value, and a channel value of a respective one of the plurality of water waves;
determining a plurality of water height values of the plurality of water waves of the water flow, each of the plurality of water height values being associated with a product of a direction weight value and an in-situ profile buffer value of a respective one of the plurality of water waves;
determining a plurality of surface normal vectors of the plurality of water waves of the water flow based on gradient vectors associated with the plurality of water height values; and
rendering the water flow based on the plurality of water height values and the plurality of surface normal vectors.

2. The method of claim 1, wherein the channel value of the respective one of the plurality of water waves includes one of a first channel value indicating a horizontal displacement of the respective one of the plurality of water waves, a second channel value indicating a vertical displacement of the respective one of the plurality of water waves, a third channel value indicating a derivative of the first channel value, and a fourth channel value indicating a derivative of the second channel value.

3. The method of claim 1, wherein the calculating further comprises:
determining a first phase value of the water flow based on (i) a product of a first wave number and a projected position of the respective one of the plurality of water waves in the domain minus (ii) a product of an angular frequency associated with the first wave number and a first time moment;
determining a second phase value of the water flow based on (i) a product of the first wave number and an updated projected position minus (ii) the product of the angular frequency associated with the first wave number and the first time moment, the updated projected position being equal to the projected position minus a spatial periodicity parameter;
determining a first initial channel value based on the first phase value and a second initial channel value based on the second phase value;
determining (i) a first weight value based on a ratio of the projected position to the spatial periodicity parameter and (ii) a second weight value as one minus the first weight value;
determining (i) a first cubic bump value based on the first weight value and (ii) a second cubic bump value based on the second weight value; and
determining a first channel value as a sum of (i) a product of the first weight value and the first initial channel value and (ii) a product of the second weight value and the second initial channel value.

4. The method of claim 3, wherein the first cubic bump value is based on x²(2|x|−3)+1 when an absolute value of the x is less than 1, the x being the first weight value.

5. The method of claim 3, wherein the calculating further comprises:
determining a first wavelength as a ratio of 2π to the first wave number; and
determining a first one of the plurality of profile buffer values based on a product of the first wavelength, a wave basis value defined according to a Phillips spectrum value associated with the first wave number, and the first channel value.

6. The method of claim 1, wherein the plurality of profile buffer values includes a first subset calculated based on a first group of angular frequencies associated with a first wave propagation velocity of the water flow and a second subset calculated based on a second group of angular frequencies associated with a second wave propagation velocity of the water flow.

7. The method of claim 1, wherein the determining the plurality of water height values further comprises:
determining a first direction weight value based on (i) a coordinate of a first position in a first subregion of the plurality of subregions of the domain and (ii) a wave direction of one of the plurality of water waves at the first position;
determining a first in-situ profile buffer value based on an interpolated value between two adjacent profile buffer values of the first in-situ profile buffer value; and
determining a first water height value of the plurality of water height values based on a product of the first direction weight value and the first in-situ profile buffer value.

8. The method of claim 7, wherein the first direction weight value is equal to 1 minus min(C, min (diffa, TAU−diffa))/C, the diffa being equal to abs(theta_p−theta_i), the theta_p being a primary wave direction of the first subregion and the theta_i being the wave direction of the one of the plurality of water waves at the first position, C being a constant, and TAU being equal to 2π.

9. The method of claim 6, wherein the determining the plurality of water height values of the water flow further comprises:
determining a first water height value of the plurality of water height values based on a weighted combination of a first subset water height value calculated according to a first one of the first subset of the plurality of profile buffer values and a second subset water height value calculated according to a first one of the second subset of the plurality of profile buffer values.

10. The method of claim 8, wherein the C is defined as (SEG_HW)/(FINE_DIR_NUM)*TAU, SEG_HW being equal to a product of SEG_PER_DIR and INT_NUM, and INT_NUM being based on a maximum wave direction difference of wave direction differences between the plurality of water waves in the first subregion and neighboring subregions of the first subregion in the plurality of subregions, FINE_DIR_NUM and SEG_PER_DIR being defined in the plurality of initial values.

11. The method of claim 10, further comprising:
determining the wave direction of the one of the plurality of water waves at the first position in the first subregion based on an arctangent of a ratio of a wave velocity of the one of the plurality of water waves in a first direction to the wave velocity of the one of the plurality of water waves in a second direction;
determining a wave direction of one of the plurality of water waves at an adjacent subregion of the first subregion in the plurality of subregions;
determining a wave direction difference between the wave direction at the first position and the wave direction at the adjacent subregion;
determining a minimum value between (i) the wave direction difference and (ii) two x minus the wave direction difference; and
determining the maximum wave direction difference as the minimum value of (i) the wave direction difference and (ii) two x minus the wave direction difference when the minimum value is larger than a preset value of the maximum wave direction difference.

12. The method of claim 1, wherein the determining the plurality of surface normal vectors further comprises:
determining a first gradient vector associated with a first water height value of the plurality of water height values;
determining a first component of the first gradient vector in a first direction and a second component of the first gradient vector in a second direction;
determining a first normal vector as a cross product of the first component of the first gradient vector and the second component of the first gradient vector; and
determining a first surface normal vector of the plurality of surface normal vectors based on a normalization of the first normal vector.

13. An information processing apparatus, comprising:
processing circuitry configured to:
define a plurality of initial values of a water wave function, the water wave function being configured to simulate a plurality of water waves of water flow in a domain that includes a plurality of subregions;
calculate a plurality of profile buffer values associated with the plurality of water waves of the water wave function, each of the plurality of profile buffer values being associated with a product of a wavelength, a wave basis value, and a channel value of a respective one of the plurality of water waves;
determine a plurality of water height values of the plurality of water waves of the water flow, each of the plurality of water height values being associated with a product of a direction weight value and an in-situ profile buffer value of a respective one of the plurality of water waves;
determine a plurality of surface normal vectors of the plurality of water waves of the water flow based on gradient vectors associated with the plurality of water height values; and
render the water flow based on the plurality of water height values and the plurality of surface normal vectors.

14. The information processing apparatus of claim 13, wherein the channel value of the respective one of the plurality of water waves includes one of a first channel value indicating a horizontal displacement of the respective one of the plurality of water waves, a second channel value indicating a vertical displacement of the respective one of the plurality of water waves, a third channel value indicating a derivative of the first channel value, and a fourth channel value indicating a derivative of the second channel value.

15. The information processing apparatus of claim 13, wherein the processing circuitry is configured to:
determine a first phase value of the water flow based on (i) a product of a first wave number and a projected position of the respective one of the plurality of water waves in the domain minus (ii) a product of an angular frequency associated with the first wave number and a first time moment;
determine a second phase value of the water flow based on (i) a product of the first wave number and an updated projected position minus (ii) the product of the angular frequency associated with the first wave number and the first time moment, the updated projected position being equal to the projected position minus a spatial periodicity parameter;
determine a first initial channel value based on the first phase value and a second initial channel value based on the second phase value;
determine (i) a first weight value based on a ratio of the projected position to the spatial periodicity parameter and (ii) a second weight value as one minus the first weight value;
determine (i) a first cubic bump value based on the first weight value and (ii) a second cubic bump value based on the second weight value; and
determine a first channel value as a sum of (i) a product of the first weight value and the first initial channel value and (ii) a product of the second weight value and the second initial channel value.

16. The information processing apparatus of claim 15, wherein the first cubic bump value is based on x²(2|x|−3)+1 when an absolute value of the x is less than 1, the x being the first weight value.

17. The information processing apparatus of claim 15, wherein the processing circuitry is configured to:
determine a first wavelength as a ratio of 2π to the first wave number; and
determine a first one of the plurality of profile buffer values based on a product of the first wavelength, a wave basis value defined according to a Phillips spectrum value associated with the first wave number, and the first channel value.

18. The information processing apparatus of claim 13, wherein the plurality of profile buffer values includes a first subset calculated based on a first group of angular frequencies associated with a first wave propagation velocity of the water flow and a second subset calculated based on a second group of angular frequencies associated with a second wave propagation velocity of the water flow.

19. The information processing apparatus of claim 13, wherein the processing circuitry is configured to:
determine a first direction weight value based on (i) a coordinate of a first position in a first subregion of the plurality of subregions of the domain and (ii) a wave direction of one of the plurality of water waves at the first position;
determine a first in-situ profile buffer value based on an interpolated value between two adjacent profile buffer values of the first in-situ profile buffer value; and
determine a first water height value of the plurality of water height values based on a product of the first direction weight value and the first in-situ profile buffer value.

20. A non-transitory computer readable storage medium storing instructions which when executed by at least one processor cause the at least one processor to perform:
defining a plurality of initial values of a water wave function, the water wave function being configured to simulate a plurality of water waves of water flow in a domain that includes a plurality of subregions;
calculating a plurality of profile buffer values associated with the plurality of water waves of the water wave function, each of the plurality of profile buffer values being associated with a product of a wavelength, a wave basis value, and a channel value of a respective one of the plurality of water waves;
determining a plurality of water height values of the plurality of water waves of the water flow, each of the plurality of water height values being associated with a product of a direction weight value and an in-situ profile buffer value of a respective one of the plurality of water waves;
determining a plurality of surface normal vectors of the plurality of water waves of the water flow based on gradient vectors associated with the plurality of water height values; and
rendering the water flow based on the plurality of water height values and the plurality of surface normal vectors.
